(19) United States
(12) Patent Application Publication
(10) Pub. No.: US 2005/0224723 A1
(43) Pub. Date: Oct. 13, 2005

(54) Ion beam apparatus and method of implanting ions

(76) Inventor: Seung-Won Chae, Yongin-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/075,909

(22) Filed: Mar. 10, 2005

(30) Foreign Application Priority Data
Apr. 9, 2004 (KR) 2004-0024342

(51) Int. Cl. H01J 37/317

(52) U.S. Cl. 250/492.21

(57) ABSTRACT

An ion beam apparatus and a method of selecting desired beam are disclosed. An ion source generates ions, a mass spectrometer extracts desired ion species, and a mirror selectively blocks ions having high mass and pass ions having low mass.

### BACKGROUND OF THE INVENTION

1. Field of the Invention

The present invention generally relates to an ion beam apparatus. More particularly, the present invention generally relates to an ion beam apparatus to implant ions into a wafer, and a method of selecting the ions.

A claim of priority is made to Korean Patent Application 2004-24342, the contents of which are hereby incorporated by reference.

2. Description of the Related Arts

Rapid developments in the information and communication field and the readily availability of information media such as computers, have brought about a rapid progress in semiconductor devices. Higher integration of the semiconductor devices has reduced featured sizes of individual elements formed on a substrate.

To manufacture the semiconductor devices, an ion implantation process and a thermal diffusion process, techniques of implanting and diffusing conductive impurities, respectively, into a silicon substrate, for example a Complementary Metal Oxide Semiconductor (CMOS), have become standard manufacturing techniques. The ion implantation technique has been employed since the 1960s. Recently, a more precise impurity control technique consistent with the higher integration and high density requirements for a Large Scale Integrated Circuit (LSI) is required. In addition, improved reproducibility and processes capability are required.

Conventional ion implantation apparatuses and methods are disclosed, for example, in U.S. Pat. No. 4,922,106 and U.S. Pat. No. 6,635,880.

FIG. 1 is a sectional view schematically illustrating an example of a conventional ion implantation apparatus.

Referring to FIG. 1, an ion beam apparatus includes an ion source 10, which generates ions and supplies an ion beam 12. A mass spectrometer 20 selects a desired ion species to be implanted into a wafer 52.

Mass spectrometer 20 includes a dipole magnet 22, which deflects desired ions species in a form of ion beam 12 through an aperture 26. Undesired ions 12a, 12b are blocked by a mask 24.

An angle correction magnet 40 corrects ion beam 12 passed through aperture 26 from a diverging ion beam to a ribbon ion beam 42 having substantially parallel ion trajectories. Angle correction magnet 40 generates a magnetic field 80 in a gap 82.

Undesired ions 12a, 12b may be generated in a main acceleration portion of ion source 10. Such undesired ions 12a, 12b have a deflection angle different from the deflection angle of ion beam 12, thus these undesired ions 12a, 12b are blocked by mask 24.

Although some ions supplied from ion source 10 have the same or similar mass, the charge volume and energy may be different from each other, thus ions having different charge volume may pass through mass spectrometer 20 and implant into wafer 52 located on an end station 50. End station 50 includes a scanner 60 to move wafer 52 perpendicular to a path of ribbon ion beam 42.

Further, some ions may have the same charge volume but different masses, these ions also pass through mass spectrometer 20 and implanted into wafer 52.

For example, ions of phosphorus, P⁺ ions, a single charged cation having about 40 KeV energy, and P⁺⁺ ions, a double charged cation having about 80 KeV energy have the same deflection angle, and both pass through mass spectrometer 20.

Also, a P₄⁺ ion having about 40 KeV energy is divided into P₂⁰ molecules and P₂⁺ ions, each having about 20 KeV energy. The P₂⁺ ions may pass together with the P⁺ ions through mass spectrometer 20 with the same deflection angle. In this case, there is no method to distinguish and separate between the desired and undesired ion beams. Micro quantities of undesired ions can be fatal to a wafer.

Accordingly, an ion beam apparatus and a method thereof capable of distinguishing among ions having the same or similar mass and ions having different energies and different charges supplied from an ion source is required.

### SUMMARY OF THE INVENTION

According to one aspect of the present invention, an ion beam apparatus includes an ion source which generates an ion beam, a mass spectrometer which selects a desired ion species from the ion beam generated from the ion source, an ion filter member which receives ions from the mass spectrometer, and blocks ions having a first energy and passes ions having a second energy, the second energy being higher than the first energy, through an aperture formed in the ion filter member, and an end station to support a wafer, wherein the ions that passed through the opening of the ion filter member are implanted on a surface of the wafer.

According to another aspect, An ion beam apparatus includes an ion source which generates an ion beam, a deposition magnet to deflect a desired ion beam generated from the ion source to a first aperture formed in a mask, an ion filter member which receives ions from the mass spectrometer, and blocks ions having a first energy and passes ions having a second energy, the second energy being higher than the first energy, through a second aperture formed in the ion filter member, and an end station to support a wafer, wherein the ions that passed through the second aperture of the ion filter member are implanted on a surface of the wafer.

The present invention also discloses a method of selecting ions generated from an ion beam apparatus by generating ions in an ion source, supplying the ions to a mass spectrometer, wherein the mass spectrometer selects a desired ion species from the ion beam to be implanted in a wafer, passing desired ions species through an ion filter member, wherein the ion filter member blocks ions having a first energy and passes ions having a second energy, the second energy being higher than the first energy, through an aperture formed in the ion filter member, and implanting ions passed through the aperture of the ion filter member onto a surface of a wafer.

### BRIEF DESCRIPTION OF THE DRAWINGS

The present invention will become more fully understood from the detailed description given hereinbelow and the accompanying drawings which are given by way of illustration only wherein:

FIG. 1 is a sectional view schematically illustrating a conventional ion implantation apparatus;

FIG. 2 is a plan view schematically illustrating an ion implantation apparatus according to an exemplary embodiment of the present invention; and

FIG. 3 illustrates an ion extracting method according to an exemplary embodiment of the invention.

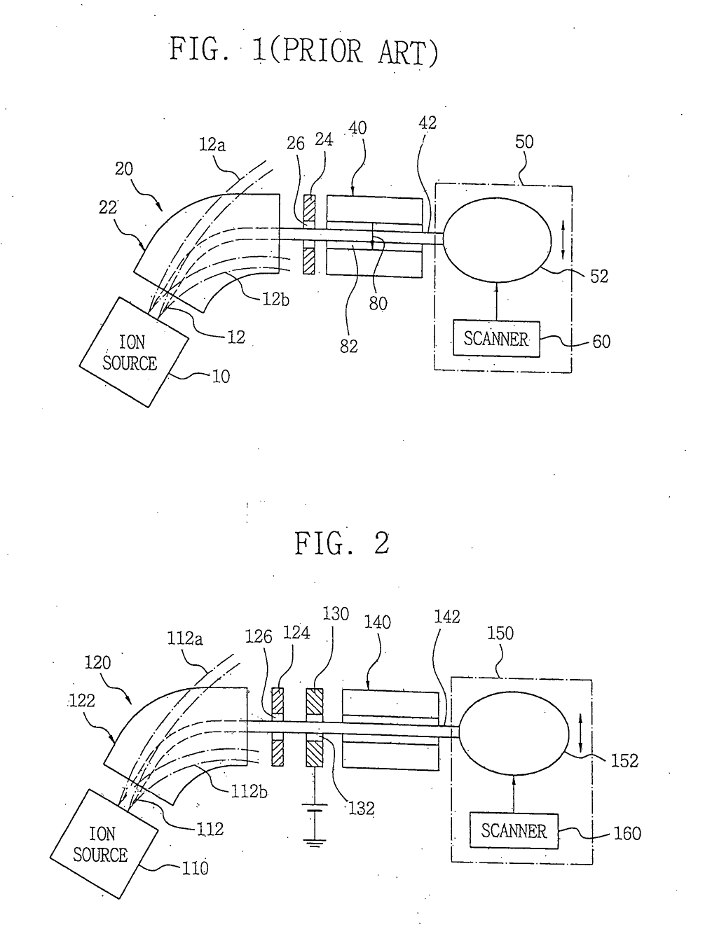

### DETAILED DESCRIPTION

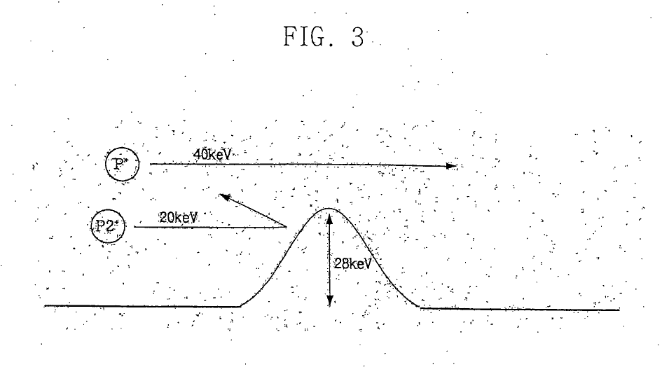

Hereinafter, exemplary embodiments of the present invention will be described in detail with reference to FIGS. 2 and 3. It will be understood by those skilled in the art that the present invention can be embodied by numerous different types and is not limited to the following described embodiments. The following various embodiments are exemplary in nature.

FIG. 2 is a plan view schematically illustrating an ion implantation apparatus according to an exemplary embodiment of the present invention.

Referring to FIG. 2, an ion beam apparatus includes an ion source 110, which generates ions and supplies an ion beam 112; a mass spectrometer 120 selects a desired ion species to be implanted into a wafer 152; an ion beam filter member 130 selectively blocks first ions having low energy an aperture 132 formed therein, and allows second ions having high energy to pass through; an end station 150 to support a wafer 152; and, a scanner 160 to move wafer 52 to the path of a ribbon ion beam 142. Ion source 110, although not shown, further includes a source gas supply part to supply a source gas such as phosphorus or arsenic, a filament to discharge hot electrons to charge the source gas, a suppression electrode to capture secondary electrons emitted from the source gas, and an acceleration electrode to accelerate the source gas ions in a single direction.

The source gas collides with the excited electrons to generate several different charged ions. In addition, ions having various masses are also generated. For example, when phosphorus is used as the source gas, ion source 110 generates P⁺ ions and P⁺⁺ ions. Further, ion source 110 also generates P⁺ ions, P₂⁺ ions and P₄⁺ ions, which all have different masses.

Mass spectrometer 120 includes a decomposition magnet 122 that is vertical to the direction of an ion beam 112, to selectively extract a desired ion species from the ions accelerated by the acceleration electrode, thus so as to have a deflection angle in conformity with mass of the ion. A desired ion species having the same or similar deflection angle pass an aperture 126 in a mask 124 as ion beam 112, and undesired species 112a, 112b are blocked by mask 124.

The ion beam apparatus further includes an angle correction magnet 140, which converts ion beam 112 from a diverging ion beam into a ribbon ion beam.

The following electrical energy, kinetic energy and centripetal force equation describes ions passing through mass spectrometer 120.
[Equation]

$$r = \frac{const}{B} \sqrt{\frac{m V}{Q}}$$

where “r” is a radius of a curvature from a center of the deflection angle; “const” is a constant; “B” is a magnet; “m” is the mass of an ion; “V” is an energy contained in the ion; and, “Q” is a charge volume of the ion.

If different ion species having the same mass but different energies are supplied from ion source 110 to mass spectrometer 120, the ion species have the same radius of curvature.

For example, P⁺ ions (a first ion) supplied from ion source 110 have about 40 KeV of energy and pass through mass spectrometer 120, and P⁺⁺ ions (a second ion) have about 80 KeV of energy and also pass through mass spectrometer 120. P⁺ ions and P⁺⁺ ions have the same radius of curvature, therefore, these different ion species pass through aperture 126.

In the present invention, ion beam filter member 130 is made of a conductive material, and when a voltage is applied to ion beam filter member 130 an energy barrier is formed. The energy barrier may form a potential higher than 40 KeV but lower than 80 KeV to block the P⁺ ions having low energy, and allowing P⁺⁺ ions having high energy to pass through aperture 132. The P⁺⁺ ions decelerate prior to passing through the energy barrier and subsequently accelerate after passing through the energy barrier. Thus, energy of P⁺⁺ ions is not affected.

Therefore, ion species having high energy can be selectively implanted into a surface of wafer 152, thereby increasing the production yield.

However, Some ion species with different masses also have the same radius of curvature.

For example, P₄⁺ ions have about 40 KeV of energy and pass through mass spectrometer 120. In mass spectrometer 120, the P₄⁺ ions are divided into P₂⁺ ions and P₂⁰ molecules, each species having about 20 KeV of energy. The P₂⁺ ions pass through mass spectrometer 120. If P⁺ ions have about 40 KeV of energy and passes through mass spectrometer 120, P₂⁺ ions and P⁺ ions have different energy, but have the same or similar radius of curvature. Thus, P₂⁺ ions and P⁺ ions pass through the aperture 126 of mask 124.

In the present invention ion beam filter member 130 forms an energy barrier with a potential that is higher than 20 KeV but lower than 40 KeV to block P₂⁺ ions having low energy, and allowing P⁺ ions having high energy to pass through aperture 132.

At this time, if P₂⁺ ions are implanted into the surface of wafer 152 with P⁺ ions, an ion implantation depth of P₂⁺ ions is shallower as compared with the P⁺ atomic ions, thus a uniformity defect may be caused by a deviation of the ion implantation depth.

The P⁺ ions passing through ion beam filter member 130 decelerate prior to passing through the energy barrier, and then subsequently accelerate after passing through the energy barrier. Thus, energy of P⁺ ions is not affected.

Therefore, the same ion species with different masses pass through mass spectrometer 120, and ions having high energy are selectively implanted into the surface of wafer 152, thereby increasing a production yield.

A method of selecting ions for implantation will be described.

First, in ion source 110, a source gas supplied from a source gas supply part collides with excited electrons, emitting secondary electrons, and simultaneously exciting the source gas to generate charged ions. Then ion beam 112 is provided to mass spectrometer 120. The source gas is phosphorus or arsenic, and when it collides with the excited electrons generates a plurality of ion species. The ion species may have various masses. For example, if phosphorus is used as the source gas, it can generate P⁺ and P⁺⁺ ions. Also, ions such as P₂⁺ and P₄⁺ having different masses different than P⁺ and P⁺⁺ ions are generated. Subsequently, in mass spectrometer 120, ions, which have different deflection angle pass through decomposition magnet 122.

A voltage higher than about 40 KeV and lower than about 80 KeV is applied to ion beam filter member 130, so as to block P⁺ ions having low energy of about 40 KeV, and to selectively allow P⁺⁺ ions having high energy of about 80 KeV to pass through an aperture 132. The P⁺⁺ ions decelerate prior to passing through mirror 130, and then accelerate and proceed in one direction with the same energy.

In the case where P₄⁺ ions with energy of about 40 KeV is supplied to mass spectrometer 120, P₄⁺ ions is divided into P₂⁺ ions and P₂⁰ molecules, wherein each ions have energy of 20 KeV. P⁺ ions pass through mass spectrometer 120, and P⁺ ions about 40 KeV of energy and passes through mass spectrometer 120; P₂⁺ ions and P⁺ ions have different energy but the same or similar radius of curvature, thus P₂⁺ ions and P⁺ ions pass through aperture 126.

Ion beam filter member 130 forms an energy barrier with a potential of about 28 KeV as shown in FIG. 3, and P⁺ ion having high energy can selectively pass through aperture 132. As shown in FIG. 3, P⁺ ions having high energy can proceed along the direction of the arrow, but P₂⁺ ions having low energy is blocked by the energy barrier. Though not depicted in FIG. 3, a transverse axis indicates a distance, and a longitudinal axis indicates an energy level.

It will be apparent to those skilled in the art that modifications and variations can be made in the present invention without deviating from the scope of the invention.

1. An ion beam apparatus, comprising:
an ion source which generates an ion beam;
a mass spectrometer which selects a desired ion species from the ion beam generated from the ion source;
an ion filter member which receives ions from the mass spectrometer, and blocks ions having a first energy and passes ions having a second energy, the second energy being higher than the first energy, through an aperture formed in the ion filter member; and
an end station to support a wafer, wherein the ions that passed through the opening of the ion filter member are implanted on a surface of the wafer.

2. The apparatus of claim 1, wherein a voltage is applied to the ion filter member to form an energy barrier potential higher than about 40 KeV and lower than about 80 KeV, or an energy barrier potential higher than about 20 KeV and lower than about 40 KeV.

3. The apparatus of claim 1, wherein the ion filter member blocks ions having a first charge volume, and passes through the aperture ions having second charge volume, and wherein the second charge volume is higher then the first volume.

4. The apparatus of claim 1, wherein the ion filter member blocks ions having a first mass, and passes through the aperture ions having a second mass, and wherein the first mass is higher than the second mass.

5. The apparatus of claim 1, wherein the mass spectrometer further comprises a deposition magnet.

6. The apparatus of claim 1, further comprising a mask having an aperture formed therein, wherein the mask is disposed between the mass spectrometer and the ion filter member.

7. The apparatus of claim 1, wherein the end station further comprises a scanner to move the wafer in a direction perpendicular to the ion beam.

8. The apparatus of claim 1, further comprising an angle correction magnet disposed between the ion filter member and the end station.

9. An ion beam apparatus, comprising:
an ion source which generates an ion beam;
a deposition magnet to deflect a desired ion beam generated from the ion source to a first aperture formed in a mask;
an ion filter member which receives ions from the mass spectrometer, and blocks ions having a first energy and passes ions having a second energy, the second energy being higher than the first energy, through a second aperture formed in the ion filter member; and
an end station to support a wafer, wherein the ions that passed through the second aperture of the ion filter member are implanted on a surface of the wafer.

10. The apparatus of claim 10, wherein the deposition magnet is disposed in a mass spectrometer.

11. The apparatus of claim 11, further comprising:
an angle correction magnet disposed between the ion filter member and the end station; and
a scanner disposed on the end station to move the wafer in a direction perpendicular to the ion beam.

12. The apparatus of claim 1, wherein a voltage is applied to the ion filter member to form an energy barrier potential higher than about 40 KeV and lower than about 80 KeV, or an energy barrier potential higher than about 20 KeV and lower than about 40 KeV.

13. A method of selecting ions generated from an ion beam apparatus, comprising:
generating ions in an ion source;
supplying the ions to a mass spectrometer, wherein the mass spectrometer selects a desired ion species from the ion beam to be implanted in a wafer;
passing desired ions species through an ion filter member, wherein the ion filter member blocks ions having a first energy and passes ions having a second energy, the second energy being higher than the first energy, through an aperture formed in the ion filter member; and
implanting ions passed through the aperture of the ion filter member onto a surface of a wafer.

14. The method of claim 13, wherein the ion filter member blocks ions having a first charge volume, and passes through the aperture ions having a second charge volume, and wherein the second charge volume being higher then the first charge volume.

15. The method of claim 13, wherein the ion filter member blocks ions having a first mass, and passes through the aperture ions having a second mass, and wherein the first mass is higher than the second mass.

16. The method of claim 13, wherein undesired ion beams are blocked by a mask disposed between the mass spectrometer and the ion filter member, and the desired ion beam is passed through an aperture formed in the mask.

17. The method of claim 16, wherein a deposition magnet disposed in the mass spectrometer which deflects the desired ion beam to the aperture of the mask.

18. The method of claim 13, wherein an angle correction magnet disposed between the ion filter member and the end station, and deflects the desired ion species and converts the ion beam from a diverging ion beam to a ribbon beam.

19. The method of claim 13, wherein the ion filter member forms an energy barrier potential higher than about 40 KeV and lower than about 80 KeV.

20. The method of claim 13, wherein the ion filter member forms an energy barrier potential higher than about 20 KeV and lower than about 40 KeV.
